(19) United States
(12) Patent Application Publication
(10) Pub. No.: US 2021/0041733 A1
(43) Pub. Date: Feb. 11, 2021

(54) ARRAY SUBSTRATE, METHOD MANUFACTURING SAME AND TOUCH DISPLAY PANEL

(71) Applicant: WUHAN CHINA STAR OPTOELECTRONICS TECHNOLOGY CO., LTD., Wuhan (CN)

(72) Inventors: Fei AI, Wuhan (CN); Dewei Song, Wuhan (CN)

(73) Assignee: WUHAN CHINA STAR OPTOELECTRONICS TECHNOLOGY CO., LTD., Wuhan (CN)

(21) Appl. No.: 16/613,419

(22) PCT Filed: Oct. 18, 2019
(86) PCT No.: PCT/CN2019/111997

§ 371 Date: Nov. 14, 2019

(30) Foreign Application Priority Data
Aug. 9, 2019 (CN) 201910732514.9

(51) Int. Cl. G02F 1/1333; G02F 1/1362; G02F 1/1343; G02F 1/1368; G06F 3/041

(52) U.S. Cl. CPC G02F 1/13338; G02F 1/136286; G02F 1/136209; G02F 1/134363; G02F 1/1368; G06F 2203/04103; G06F 3/0412; G02F 2001/136295; G02F 2001/136231; G02F 2001/134318; G02F 1/13439

(57) ABSTRACT

An array substrate, a method of manufacturing the same and a touch display panel are disclosed. An inorganic insulating layer, a plurality of common electrodes and a passivation layer are sequentially manufactured on a substrate formed with a plurality of thin film transistors and a plurality of touch signal lines. The passivation layer and the inorganic insulating layer are patterned to form a plurality of first via holes exposing drain electrodes of the thin film transistors and the touch signal lines, and to form a plurality of second via holes exposing the common electrodes in such a manner that the touch signal lines and the common electrodes are bridged through the touch electrodes formed on a surface of the passivation layer.

### FIELD OF INVENTION

The present disclosure relates to the technical field of touch display panel manufacturing, and in particular, to an array substrate, a method manufacturing the same and a touch display panel.

### BACKGROUND OF INVENTION

Liquid crystal displays (LCDs) are now mainstream in display devices, especially in low-temperature polysilicon display technology (LTPS). Since for the low-temperature polysilicon display technology, higher carrier mobility allows transistors to achieve higher switching current ratios, under the required charging current, each pixel transistor can be minimized, a transmissive area of each pixel can be increased, the panel aperture ratio can be increased, bright dots and high resolution of panels are improved, and power consumption of the panels is reduced, thereby having better viewing experience.

Since liquid crystal displays are passive display devices that adjust alignment states of the liquid crystal molecules by electric fields to realize luminous flux modulation, it is required that fine active driving matrices correspond to deflection states of the liquid crystals in each pixel region. In view of the development of low-temperature polysilicon active matrix towards continuously reduced feature sizes, the subsequent advances in photolithography have led to an exponential increase in equipment costs. Thus, how to reduce costs and simplify processes becomes hot research topics.

Accordingly, the prior art has drawbacks, and is in urgent need of improvement.

### SUMMARY OF INVENTION

The present disclosure provides an array substrate, a method manufacturing the same, and a touch display panel, which can solve the problems that equipment costs are increased and processes are complicated while low-temperature polysilicon active matrices are developed towards reduced feature sizes.

In order to solve the aforementioned problems, the technical solutions provided by the present application are as follows:

The present application provides a method of manufacturing an array substrate, comprising the following steps: step S10, providing a substrate and forming an inorganic film layer, a plurality of thin film transistors and a plurality of touch signal lines on the substrate, wherein the touch signal lines are manufactured on a surface of the inorganic film layer and on the same layer with source/drain electrodes of the thin film transistors; step S20, manufacturing an inorganic insulating layer on surfaces of the source/drain electrodes and surfaces of the touch signal lines, and forming a plurality of patterned common electrodes on a surface of the inorganic insulating layer; step S30, manufacturing a passivation layer on surfaces of the common electrodes, and patterning the passivation layer and the inorganic insulating layer by a single mask process to form a plurality of first via holes exposing the drain electrodes and the touch signal lines, and to form a plurality of second via holes exposing the common electrodes; step S40, forming a plurality of patterned pixel electrodes and a plurality of touch electrodes on a surface of the passivation layer, wherein the pixel electrodes are electrically connected to the drain electrodes through the first via holes, and the touch electrodes are electrically connected to the touch signal lines and the common electrodes respectively through the first via holes and the second via holes in such a manner that the touch signal lines and the common electrodes are bridged through the touch electrodes.

In the method of the present application, the step S10 includes the following step: step S101, manufacturing a light shielding layer on the substrate, and patterning the light shielding layer to form a plurality of light shielding blocks; step S102, sequentially manufacturing a buffer layer and a plurality of amorphous silicon layers on the light shielding blocks, patterning the amorphous silicon layers, and applying a laser annealing operation to the patterned amorphous silicon layers to form a plurality of polysilicon layers; step S103, sequentially manufacturing a gate insulating layer and a gate metal layer on the polysilicon layers, patterning the gate metal layer to form a plurality of gates, and ion-doping the polysilicon layers to form a plurality of active layers; step S104, manufacturing an interlayer insulating layer on the gates, patterning the interlayer insulating layer and the gate insulating layer by a single mask process to form a plurality of source/drain via holes exposing a plurality of source/drain heavily doped areas of the active layers; step S105, manufacturing a source/drain metal layer on the interlayer insulating layer, and patterning the source/drain metal layer to form the source/drain electrodes corresponding to the source/drain via holes, and forming the touch signal lines insulated from the source/drain electrodes.

In the method of the present application, the step S103 includes the following step: performing a first patterning on the gate metal layer to form a plurality of gate intermediate blocks, and ion-doping the polysilicon layers at both sides of the gate intermediate blocks with the gate intermediate blocks as masks to form the source/drain heavily doped areas; performing a second patterning on the gate metal layer to form the gates, and ion-doping the polysilicon layers at both sides of the gates with the gates as masks, and forming lightly doped areas at two sides of an area of the polysilicon layers corresponding to the gates.

In the method of the present application, the pixel electrodes and the touch electrodes are formed by same material and simultaneously formed by the same mask process, and the material of the pixel electrodes and the touch electrodes includes one or more of indium tin oxide, indium zinc oxide, zinc oxide, indium oxide, indium gallium oxide, and aluminum zinc oxide.

In the method of the present application, material of the inorganic insulating layer comprises one or more of silicon nitride and silicon oxide.

In order to solve the above problems, the present application further provides an array substrate, comprising: a substrate; a plurality of thin film transistor layers disposed on the substrate, and the thin film transistor layers including a plurality of source/drain electrodes; a plurality of touch signal lines on the same layer with the source/drain electrodes and insulated from the source/drain electrodes; an inorganic insulating layer disposed on the touch signal lines and the source/drain electrodes; a plurality of common electrodes disposed on the inorganic insulating layer and spaced apart from each other; a passivation layer disposed on the common electrodes; a plurality of pixel electrodes disposed on the passivation layer and electrically connected to the source/drain electrodes of the thin film transistors through a plurality of first via holes, respectively; a plurality of touch electrodes disposed on the same layer with the pixel electrodes, and the touch electrodes electrically connected to the touch signal lines and the common electrodes, respectively.

In the array substrate of the present application, the first via holes are disposed to correspond to the touch signal lines and the source/drain electrodes, and the first via holes penetrate the passivation layer and the inorganic insulating layer and are in contact with the touch signal lines and the source/drain electrodes, and the touch signal lines are electrically connected to the touch electrodes through the corresponding first via holes.

In the array substrate of the present application, a plurality of second via holes are formed on a position of the passivation layer corresponding to the common electrodes, and the touch electrodes electrically connected to the common electrodes through the second via holes.

In the array substrate of the present application, the touch electrodes are respectively located at a gap between the two pixel electrodes adjacent to each other, and are insulated from the pixel electrodes, and the touch electrodes are distributed in a grid shape or distributed in blocks and spaced apart from each other.

In order to solve the above problems, the present application further provides a touch display panel comprising the array substrate as described above, a color filter substrate disposed opposite to the array substrate, and a liquid crystal layer between the array substrate and the color filter substrate.

The present disclosure has the beneficial effects that the organic planarization layer in the conventional process is replaced with the inorganic insulating layer, which eliminates a mask process performed on the organic planarization layer in the conventional process. Specifically, photolithography performed on the inorganic insulating layer is conducted simultaneously in photolithography process performed on the passivation layer to eliminate a mask process to simplify the processes and reduce the costs, thereby facilitating the developments of the low-temperature polysilicon active matrices towards reduced feature sizes. In addition, use of inorganic material in place of organic material of the planarization layer in the conventional structure can also prevent the contamination of the sputtering chamber caused by the subsequent formation of the common electrodes by the sputtering process.

### BRIEF DESCRIPTION OF THE DRAWINGS

To describe the technical solutions of the embodiments or the prior art more clearly, the following outlines briefly the accompanying drawings for describing the embodiments of the present disclosure or the prior art. Apparently, the accompanying drawings described below are merely about some embodiments of the present disclosure, and persons of ordinary skill in the art can derive other drawings from the accompanying drawings without any creative effort.

FIG. 1 is a flowchart of the manufacturing method of an array substrate according to the embodiment of the present disclosure.

FIG. 2 is a flowchart of step 10 in the manufacturing method of an array substrate according to the embodiment of the present disclosure.

FIGS. 3-14 are schematic views showing the manufacturing processes of an array substrate according to the embodiment of the present disclosure.

FIG. 15 is a schematic view showing structure of an array substrate according to the embodiment of the present disclosure.

### DETAILED DESCRIPTION OF EMBODIMENTS

The following embodiments are referring to the accompanying drawings for exemplifying specific implementable embodiments of the present disclosure. Furthermore, directional terms described by the present disclosure, such as “upper”, “lower”, “front”, “back”, “left”, “right”, “inner”, “outer”, “side” and etc., are only directions by referring to the accompanying drawings, and thus the used directional terms are used to describe and understand the present disclosure, but the present disclosure is not limited thereto. In the drawings, structure-like elements are labeled with like reference numerals.

The present application can solve the technical problems of increase in equipment cost and a complicated process resulting from development of existing low-temperature polysilicon active matrices toward reduced feature sizes. The present embodiments are capable of solving the defects.

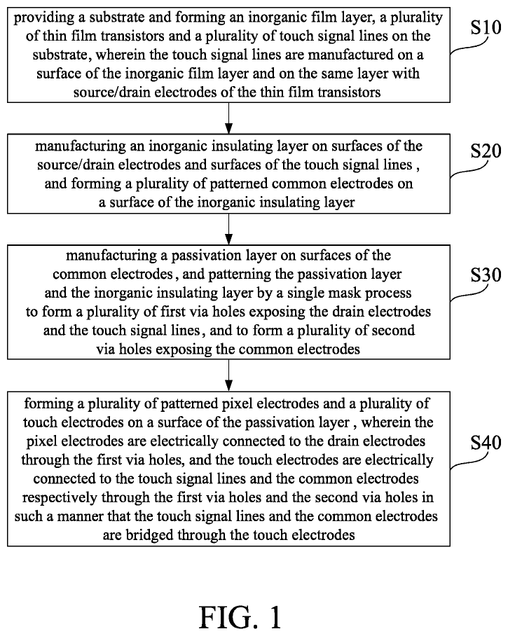

As shown in FIG. 1, a flowchart showing a manufacturing method of an array substrate provided by an embodiment of the present disclosure is illustrated, the method comprising the following steps.

A step S10 includes providing a substrate, and forming an inorganic film layer, a plurality of thin film transistors and a plurality of touch signal lines on the substrate, wherein the touch signal lines are manufactured on a surface of the inorganic film layer and on the same layer with source/drain electrodes of the thin film transistors.

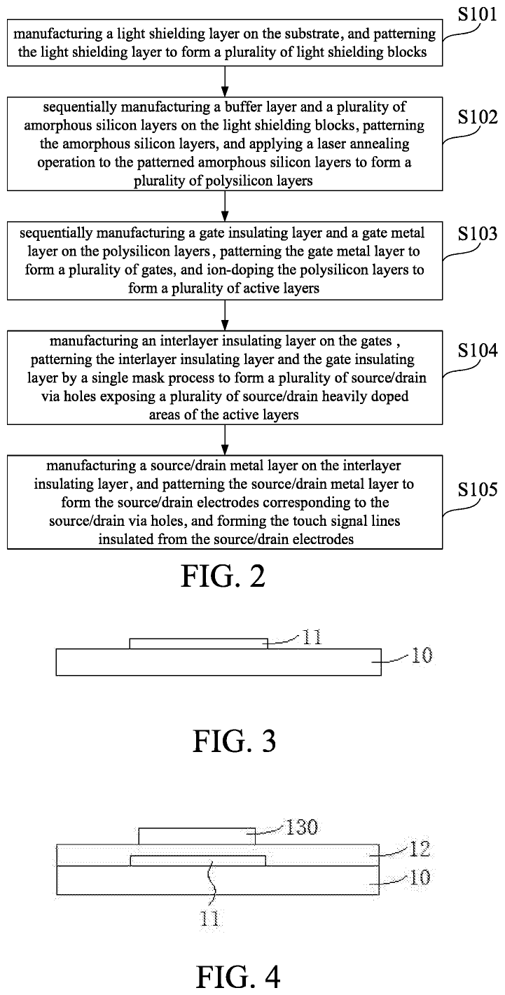

Specifically, as shown in FIGS. 2-10, the step S10 includes the following steps.

As shown in FIG. 3, a step S101 includes manufacturing a light shielding layer (not shown) on the substrate 10, and patterning the light shielding layer to form a plurality of light shielding blocks 11 after a first mask process.

As shown in FIG. 4, a step S102, includes sequentially manufacturing a buffer layer 12 and a plurality of amorphous silicon layers on the light shielding blocks 11, applying a laser annealing operation to the patterned amorphous silicon layers in such a manner that amorphous silicon is formed into polysilicon, and conducting a second mask process to form a plurality of polysilicon layers 130 after patterning.

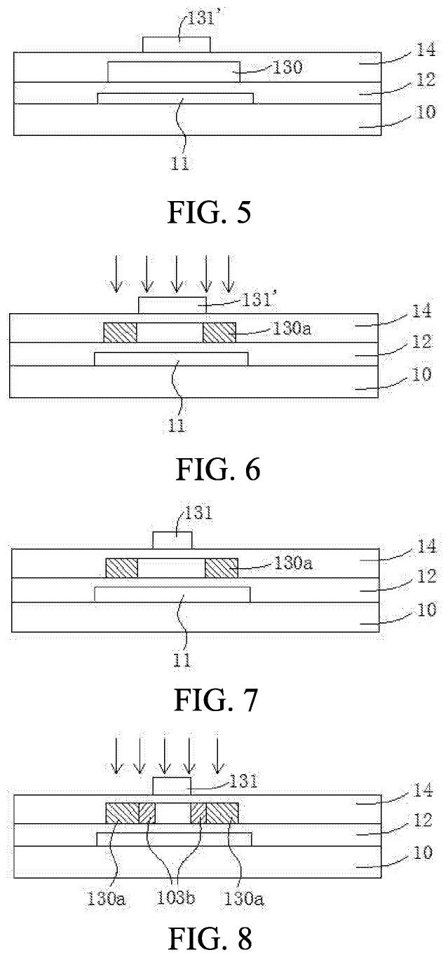

As shown in FIGS. 5-8, a step S103 includes sequentially manufacturing a gate insulating layer 14 and a gate metal layer (not shown) on the polysilicon layers 130, performing a third mask process on the gate metal layer. Specifically, a first patterning is performed on the gate metal layer to form a plurality of gate intermediate blocks 131′. The gate intermediate blocks 131′ is used as masks, and nitrogen-doping is performed on the polysilicon layers 130 at both sides of the gate intermediate blocks 131′ to form the source/drain heavily doped areas 130a at both sides of the polysilicon layers 130. Then, a second patterning is performed on the gate metal layer to form the gates 131. The gates 131 is used as masks, nitrogen-doping is performed the polysilicon layers 130 at both sides of the gates 131, and lightly doped areas 130b is formed at two sides of an area of the polysilicon layers 130 corresponding to the gates 131 so as to form the active layer. A portion of the polysilicon layers 130 corresponding to the gates 131 serves as a channel region of the active layer.

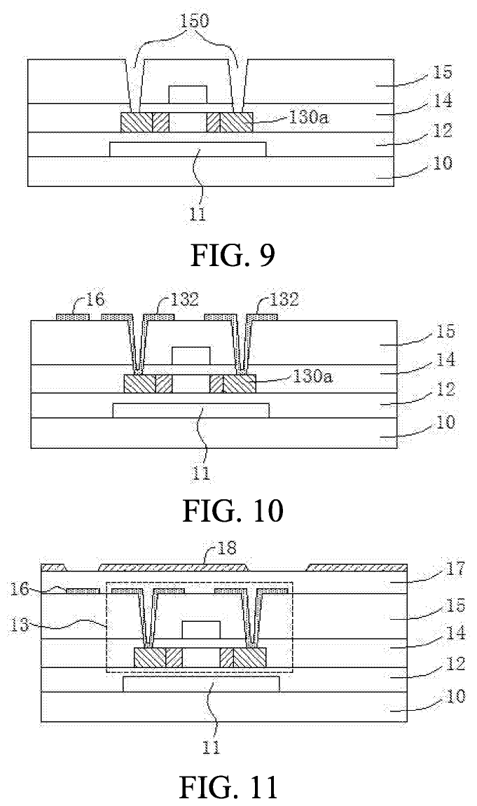

As shown in FIG. 9, a step S104 includes manufacturing an interlayer insulating layer 15 on the gates 131, patterning the interlayer insulating layer 15 and the gate insulating layer 14 by a fourth mask process to form a plurality of source/drain via holes 150 exposing a plurality of source/drain heavily doped areas 130a of the active layers.

As shown in FIG. 10, a step S105 includes manufacturing a source/drain metal layer on the interlayer insulating layer 15, and performing a fifth mask process on the source/drain metal layer to pattern the source/drain metal layer to form the source/drain electrodes 132 corresponding to the source/drain via holes 150, and to form the touch signal lines 16 insulated from the source/drain electrodes 132.

As shown in FIG. 11, a step S20 includes manufacturing an inorganic insulating layer 17 on surfaces of the source/drain electrodes 132 and surfaces of the touch signal lines 16, manufacturing a first electrode layer on a surface of the inorganic insulating layer 17, and performing a sixth mask process on the first electrode layer to forming a common electrode 18 after patterning. Material of the inorganic insulating layer 17 includes, but is not limited to, one or more of silicon nitride and silicon oxide.

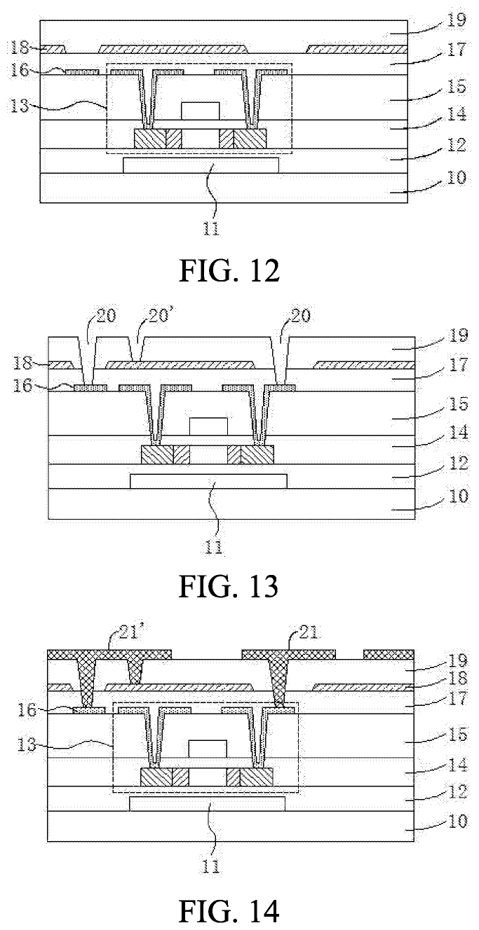

As shown in FIGS. 12 and 13, a step S30 includes manufacturing a passivation layer 19 on surfaces of the common electrodes 18, and patterning the passivation layer 19 and the inorganic insulating layer 17 by a seventh mask process to form a plurality of first via holes 20 exposing the drain electrodes 132 and the touch signal lines 16 after patterning, and to form a plurality of second via holes 20′ exposing the common electrodes 18.

In an embodiment, material of the inorganic insulating layer 17 is the same as material of the passivation layer 19, or material of the inorganic insulating layer 17 and material of the passivation layer 19 are respectively one of silicon nitride and silicon oxide.

Specifically, the seventh mask process includes two etching processes. Take the passivation layer 19 as silicon nitride and the inorganic insulating layer 17 as silicon oxide as examples. The first etching process is performed on the passivation layer 19 to form the second via holes 20′, and the second etching process is performed on the inorganic insulating layer 17 to form the first via holes 20.

As shown in FIG. 14, a step S40 includes manufacturing a second electrode layer on a surface of the passivation layer 19, and performing an eighth mask process on the second electrode layer to form a plurality of pixel electrodes 21 and a plurality of touch electrodes 21′ after patterning. The pixel electrodes 21 are electrically connected to the drain electrodes 132 through the first via holes 20, and the touch electrodes 21′ are electrically connected to the touch signal lines 16 and the common electrodes 18 respectively through the first via holes 20 and the second via holes 20′ in such a manner that the touch signal lines 16 and the common electrodes 18 are bridged through the touch electrodes 21′.

Specifically, material of the pixel electrodes 21, the touch electrodes 21′, and the common electrodes 18 includes, but is not limited to, one or more of indium tin oxide, indium zinc oxide, zinc oxide, indium oxide, indium gallium oxide, and aluminum zinc oxide.

In the present embodiment, the organic planarization layer in the conventional process is replaced with the inorganic insulating layer 17, which eliminates a mask process performed on the organic planarization layer in the conventional process. The inorganic insulating layer 17 does not need to be exposed. Photolithography performed on the inorganic insulating layer 17 is conducted simultaneously in photolithography process performed on passivation layer 19 to eliminate a mask process to simplify the processes and reduce the costs. The manufacturing process facilitates the development of the low-temperature polysilicon active matrices towards reduced feature sizes.

In addition, use of inorganic material in place of organic material of the planarization layer in the conventional structure can prevent decomposition of the planarization layer caused by a subsequent sputtering process forming the common electrodes 18 so as to prevent the contamination of the sputtering chamber caused by the subsequent formation of the common electrodes 18 by the sputtering process.

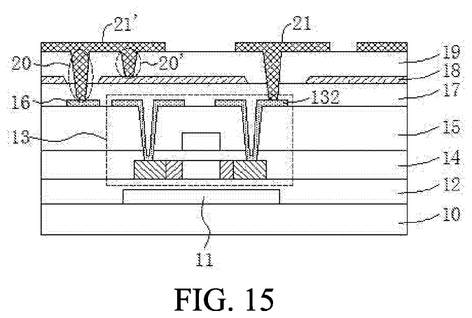

The present application further provides an array substrate manufactured by the above method, as shown in FIG. 15, the array substrate including: a substrate 10; a plurality of thin film transistor layers disposed on the substrate 10, the thin film transistor layers including an inorganic film layer and thin film transistors 13, the inorganic film layer including, but not limited to, a buffer layer 12, a gate insulating layer 14, an interlayer insulating layer 15, and the like; a plurality of touch signal lines disposed on the thin film transistor layers and on the same layer with the source/drain electrodes 132 of the thin film transistors 13, and insulated from the source/drain electrodes 132; an inorganic insulating layer 17 disposed on the touch signal lines 16; a plurality of common electrodes 18 disposed on the inorganic insulating layer 17 and spaced apart from each other; a passivation layer 19 disposed on the common electrodes 18; a plurality of pixel electrodes 21 disposed on the passivation layer 19 and electrically connected to the source/drain electrodes 132 of the thin film transistors 13 through a plurality of first via holes 20 penetrating the passivation layer 19 and the inorganic insulating layer 17, respectively; a plurality of touch electrodes 21′ disposed on the same layer with the pixel electrodes 21, and the touch electrodes 21′ electrically connected to the touch signal lines 16 and the common electrodes 18, respectively. Specifically, the first via holes 20 are disposed to correspond to the touch signal lines 16 and the source/drain electrodes 132. The first via holes 20 are in contact with the touch signal lines 16 and the source/drain electrodes 132. The touch signal lines 16 are electrically connected to the touch electrodes 21′ through the first via holes 20 corresponding thereto.

A plurality of second via holes 20′ are formed on the passivation layer 19 at a position corresponding to the common electrodes 18. The touch electrodes 21′ are electrically connected to the common electrodes 18 through the second via holes 20′.

In the present embodiment, the touch electrodes 21′ are respectively located at a gap between the two pixel electrodes 21 adjacent to each other, and are insulated from the pixel electrodes 21. In an embodiment, the touch electrodes 21′ are distributed in a grid shape or distributed in blocks and spaced apart from each other.

Specifically, the touch signal lines 16 and the common electrodes 18 are bridged by the touch electrodes 21′, and the touch electrodes 21′ are configured to generate a touch voltage signal when subjected to a pressing operation, and transmit touch voltage signal to the corresponding common electrodes 18, in such a manner that voltage of the common electrodes 18 changes to implement touch function.

Undoubtedly, the array substrate may also include other conventional film layers, and the present disclosure is not limited herein.

The present application further provides a touch display panel comprising the array substrate as described in the above embodiments, a color filter substrate disposed opposite to the array substrate, and a liquid crystal layer between the array substrate and the color filter substrate. Refer to the description in the above embodiments for the specific structure of the array substrate, and no further details are provided in this embodiment.

As shown in FIG. 15, during the display phase of the touch display panel, the thin film transistors 13 are turned on and provide pixel voltage signal for the pixel electrodes 21, and common voltage signal is provided by the touch signal lines 16 to the common electrodes 18 through the touch electrodes 21′, and voltage difference is formed between the pixel electrodes 21 and the common electrodes 18 to drive liquid crystal molecules to deflect, so that the touch display panel performs display function.

During the touch phase of the touch display panel, the touch electrodes 21′ generate touch voltage signal when pressing operation is performed, and transmit the touch voltage signal to the corresponding common electrodes 18 such that voltage of the common electrodes 18 changes to realize the touch function.

The touch display panel of the present application has advantages including simple processes and low costs, and a small size of the thin film transistors 13 can be realized to meet process requirements.

As mentioned above, although the present application has been disclosed in the above preferred embodiments, the preferred embodiments are not intended to limit the application. Various modification and retouch can be made by those skilled in the art without departing from the spirit and scope of the present application. Thus, the scope of protection of the present application is determined by the scope defined by the claims.

What is claimed is:

1. A method of manufacturing an array substrate, comprising the following steps:
step S10, providing a substrate and forming an inorganic film layer, a plurality of thin film transistors and a plurality of touch signal lines on the substrate, wherein the touch signal lines are manufactured on a surface of the inorganic film layer and on the same layer with source/drain electrodes of the thin film transistors;
step S20, manufacturing an inorganic insulating layer on surfaces of the source/drain electrodes and surfaces of the touch signal lines, and forming a plurality of patterned common electrodes on a surface of the inorganic insulating layer;
step S30, manufacturing a passivation layer on surfaces of the common electrodes, and patterning the passivation layer and the inorganic insulating layer by a single mask process to form a plurality of first via holes exposing the drain electrodes and the touch signal lines, and to form a plurality of second via holes exposing the common electrodes;
step S40, forming a plurality of patterned pixel electrodes and a plurality of touch electrodes on a surface of the passivation layer, wherein the pixel electrodes are electrically connected to the drain electrodes through the first via holes, and the touch electrodes are electrically connected to the touch signal lines and the common electrodes respectively through the first via holes and the second via holes in such a manner that the touch signal lines and the common electrodes are bridged through the touch electrodes.

2. The method of claim 1, wherein the step 10 comprises the following steps:
step S101, manufacturing a light shielding layer on the substrate, and patterning the light shielding layer to form a plurality of light shielding blocks;
step S102, sequentially manufacturing a buffer layer and a plurality of amorphous silicon layers on the light shielding blocks, patterning the amorphous silicon layers, and applying a laser annealing operation to the patterned amorphous silicon layers to form a plurality of polysilicon layers;
step S103, sequentially manufacturing a gate insulating layer and a gate metal layer on the polysilicon layers, patterning the gate metal layer to form a plurality of gates, and ion-doping the polysilicon layers to form a plurality of active layers;
step S104, manufacturing an interlayer insulating layer on the gates, patterning the interlayer insulating layer and the gate insulating layer by a single mask process to form a plurality of source/drain via holes exposing a plurality of source/drain heavily doped areas of the active layers;
step S105, manufacturing a source/drain metal layer on the interlayer insulating layer, and patterning the source/drain metal layer to form the source/drain electrodes corresponding to the source/drain via holes, and to form the touch signal lines insulated from the source/drain electrodes.

3. The method of claim 2, wherein the step 103 comprises the following steps:
performing a first patterning on the gate metal layer to form a plurality of gate intermediate blocks, and ion-doping the polysilicon layers at both sides of the gate intermediate blocks with the gate intermediate blocks as masks to form the source/drain heavily doped areas;
performing a second patterning on the gate metal layer to form the gates, and ion-doping the polysilicon layers at both sides of the gates with the gates as masks, and forming lightly doped areas at two sides of an area of the polysilicon layers corresponding to the gates.

4. The method of claim 1, wherein the pixel electrodes and the touch electrodes are formed by same material and simultaneously formed by the same mask process, and the material of the pixel electrodes and the touch electrodes includes one or more of indium tin oxide, indium zinc oxide, zinc oxide, indium oxide, indium gallium oxide, and aluminum zinc oxide.

5. The method of claim 1, wherein material of the inorganic insulating layer comprises one or more of silicon nitride and silicon oxide.

6. An array substrate, comprising:
a substrate;
a plurality of thin film transistor layers disposed on the substrate, and the thin film transistor layers including a plurality of source/drain electrodes;
a plurality of touch signal lines on the same layer with the source/drain electrodes and insulated from the source/drain electrodes;
an inorganic insulating layer disposed on the touch signal lines and the source/drain electrodes;
a plurality of common electrodes disposed on the inorganic insulating layer and spaced apart from each other;
a passivation layer disposed on the common electrodes;
a plurality of pixel electrodes disposed on the passivation layer and electrically connected to the source/drain electrodes of the thin film transistors through a plurality of first via holes, respectively;
a plurality of touch electrodes disposed on the same layer with the pixel electrodes, and the touch electrodes electrically connected to the touch signal lines and the common electrodes, respectively.

7. The array substrate of claim 6, wherein the first via holes are disposed to correspond to the touch signal lines and the source/drain electrodes, and the first via holes penetrate the passivation layer and the inorganic insulating layer and are in contact with the touch signal lines and the source/drain electrodes, and the touch signal lines are electrically connected to the touch electrodes through the corresponding first via holes.

8. The array substrate of claim 6, wherein a plurality of second via holes are formed on a position of the passivation layer corresponding to the common electrodes, and the touch electrodes electrically connected to the common electrodes through the second via holes.

9. The array substrate of claim 6, wherein the touch electrodes are respectively located at a gap between the two pixel electrodes adjacent to each other, and are insulated from the pixel electrodes, and the touch electrodes are distributed in a grid shape or distributed in blocks and spaced apart from each other.

10. A touch display panel, comprising: the array substrate according to claim 6, a color filter substrate disposed opposite to the array substrate, and a liquid crystal layer between the array substrate and the color filter substrate.
